(19) United States
(12) Patent Application Publication
(10) Pub. No.: US 2026/0212823 A1
(43) Pub. Date: Jul. 23, 2026

(54) DISPLAY APPARATUS

(71) Applicant: LG Display Co., Ltd., Seoul (KR)

(72) Inventors: Juhee EUN, Seoul (KR); Jinhun KIM, Goyang-si (KR); Juhwan BAEK, Seoul (KR); Yeonjin SA, Seoul (KR)

(73) Assignee: LG Display Co., Ltd., Seoul (KR)

(21) Appl. No.: 19/454,070

(22) Filed: Jan. 20, 2026

(30) Foreign Application Priority Data
Jan. 21, 2025 (KR) 10-2025-0009015

(51) Int. Cl. G09G 3/3233

(52) U.S. Cl. CPC G09G 3/3233; G09G 2300/0842; G09G 2310/08; G09G 2320/041; G09G 2330/021

(57) ABSTRACT

A display apparatus can include a light-emitting element, a driving transistor driving the light-emitting element, a storage capacitor sampling a threshold voltage of the driving transistor during a sampling period and programming a data voltage during a program period, and at least one thin film transistor transmitting at least one of the data voltage, a reference voltage, and a reset voltage. The display apparatus varies the sampling period according to a luminance band.

### CROSS-REFERENCE TO RELATED APPLICATION

This application claims priority to and the benefit of Korean Patent Application No. 10-2025-0009015, filed in the Republic of Korea on Jan. 21, 2025, the disclosure of which is hereby expressly incorporated by reference in its entirety.

### BACKGROUND

### Field

The present disclosure relates to a display apparatus.

### Discussion of the Related Art

An organic light-emitting display apparatus is a self-emitting type display apparatus, and thus, unlike a liquid crystal display apparatus, requires no separate light source, thereby capable of being manufactured in a lightweight and thin form. Additionally, the organic light-emitting display apparatus is not only advantageous in terms of power consumption by low voltage driving, but also has excellent color implementation, response speed, viewing angle, and contrast ratio (CR), so it has been studied as a next-generation display.

Display apparatuses are constantly being improved to provide users with clearer images by increasing the resolution and luminance of the screen.

### SUMMARY OF THE INVENTION

To driving transistors and switch transistors in the pixels of the display panel, oxide thin film transistors (TFTs) are applied. This pixel can contribute to the realization of low power consumption because the oxide TFT has the low off-current characteristic.

Meanwhile, temperature luminance sensitivity (TLS) refers to the degree of luminance change according to temperature change, and is evaluated under low and high gradation band conditions as one of the items required for product spec management. The display apparatus samples the threshold voltage Vth of the driving transistor during the sampling period, but applies the same sampling time to all bands of the low and high gradations, so there can be a drawback in that TLS optimization for each band is not satisfied.

In view of this issue, the inventors of the present application have invented a display apparatus capable of satisfying the excellent TLS characteristics of a high-luminance band and a low-luminance band in a display panel having pixels to which oxide TFTs have been applied.

An object to be accomplished according to embodiments of the present disclosure is to provide a display apparatus capable of improving TLS characteristics in all luminance bands by applying a sampling time which is varied according to the luminance band in a display panel having pixels to which oxide TFTs have been applied.

Another object to be accomplished according to embodiments of the present disclosure is to provide an improved display apparatus/device, which can address the limitations and disadvantages associated with the related art.

The present disclosure can have other objects besides the aforementioned ones, which are clearly recognizable to a person skilled in the art from the description below.

There is provided a display apparatus according to an embodiment of the present disclosure. The display apparatus varies the sampling period for sampling the threshold voltage of the driving transistor according to the luminance band in the display panel having the pixels to which the oxide TFTs have been applied.

According to an embodiment of the present disclosure, the luminance band can be divided into a plurality of bands representing a luminance range from a low luminance to a high luminance, and the sampling period can be individually set for each of the plurality of bands.

According to an embodiment of the present disclosure, the sampling period can be varied to have a longer time in a step-by-step manner as it goes from a low-luminance band to a high-luminance band.

According to an embodiment of the present disclosure, the display apparatus can improve TLS (Temperature Luminance Sensitivity) characteristics in all luminance bands by varying the sampling period for sampling the threshold voltage of the driving transistor according to the luminance band in the display panel having pixels to which oxide TFTs have been applied.

Additionally, the display apparatus according to aspects of the present disclosure can optimize the sampling period according to the luminance band by setting the sampling period individually for each of the plurality of bands representing a luminance range from a low luminance to a high luminance.

Further, the display apparatus according to aspects of the present disclosure can improve the TLS characteristics for each luminance band by applying an optimal sampling period to each of the plurality of bands representing the luminance range.

Also, the display apparatus according to aspects of the present disclosure varies the sampling time to have a longer time in a step-by-step manner as it goes from a low-luminance band to a high-luminance band, so that the shorter the sampling time is in the low-luminance band, the more excellent the TLS characteristic can be, and the longer the sampling time is in the high-luminance band, the more excellent the TLS characteristic can be.

Furthermore, the display apparatus according to aspects of the present disclosure can improve image quality by having excellent TLS characteristics regardless of the luminance band, and fulfill the spec conditions of the display panel having the pixels to which the oxide TFTs have been applied.

In addition to the effects described above, specific effects of the present invention will be described below together with specific matters for practicing the invention.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a block diagram schematically illustrating an organic light-emitting display apparatus according to an embodiment of the present disclosure;

FIG. 2 is a circuit diagram of a pixel in an organic light-emitting display apparatus according to an embodiment of the present disclosure;

FIG. 3 is a timing diagram illustrating an operation of a pixel in an organic light-emitting display apparatus according to an embodiment of the present disclosure;

FIG. 4 is a diagram illustrating that the sampling time of FIG. 3 is individually set according to the luminance band;

FIG. 5 is a diagram showing an optimal sampling time in a low-luminance band; and

FIG. 6 is a diagram illustrating an optimal sampling time in a high-luminance band.

### DETAILED DESCRIPTION OF THE EMBODIMENTS

Advantages and features of the present disclosure, and a method of achieving the advantages and features will become apparent when referring to the following embodiments described later in detail together with the accompanying drawings. However, the present disclosure is not limited to the embodiments as disclosed below, but can be embodied in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating embodiments of the present disclosure are illustrative, and the present disclosure is not limited thereto. Throughout the detailed description, like reference symbols refer to like components. Further, in describing the present disclosure, if it is determined that a detailed description of a related known technology can unnecessarily obscure the gist of the present disclosure, the detailed description thereof will be omitted. When the terms “comprise”, “include”, “have”, “be configured with”, “be comprised of”, and the like are used in the present disclosure, the presence or addition of other element can be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using terms such as “on”, “above”, “below”, and “next to”, one or more other elements can be interposed between the two elements unless “just”, “directly”, or “close” is used.

In describing a temporal relationship, for example, when the temporal order is described using terms such as “after”, “subsequent”, “next”, and “before”, the case which is not continuous can also be included unless the term “just” or “directly” is used.

When describing the flow relationship of a signal, for example, in a case where ‘a signal is transmitted from node A to node B’, it can include a case where a signal is transmitted from node A to node B via another node, unless the term ‘immediately’ or ‘directly’ is used.

It will be understood that, although the terms such as “first”, “second”, etc. can be used herein to describe various elements, these elements should not be limited by these terms. These terms are merely used to distinguish one element from another element. So, a first element referred to in the following description can represent a second element, without departing from the scope of the technical idea of the present disclosure. Further, the term “can” fully encompasses all the meanings and coverages of the term “may” and vice versa.

The individual features of the various embodiments of the present disclosure can be coupled or combined with each other in part or in whole to be interconnected and operated in a variety of technical ways, and each embodiment can be implemented independently of each other or implemented together in an associative relationship.

Hereinafter, there is disclosed a display apparatus according to an embodiment of the present disclosure, in which the temperature luminance sensitivity (TLS) characteristics can be improved for all luminance bands of the display panel having pixels to which oxide TFTs have been applied.

Hereinafter, various embodiments of the present disclosure will be described in detail with reference to the accompanying drawings. All the components of each display apparatus/device according to all embodiments of the present disclosure are operatively coupled and configured.

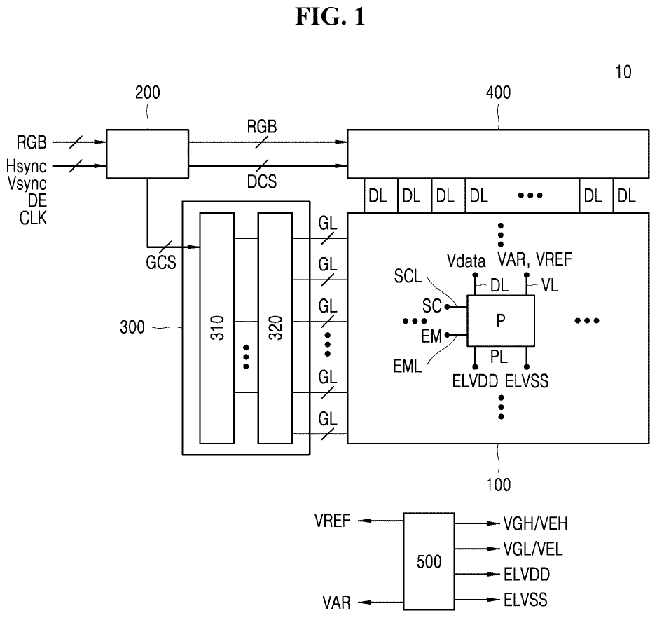

FIG. 1 is a block diagram schematically illustrating an organic light-emitting display apparatus according to an embodiment of the present disclosure.

Referring to FIG. 1, a display apparatus 10 includes a display panel 100 including a plurality of pixels P, a controller 200, a gate driving part 300 that supplies a scan signal SC to the plurality of pixels P, a data driving part 400 that supplies a data voltage Vdata to the plurality of pixels P, and a power supply unit 500 that supplies voltages required to drive the plurality of pixels P.

In the display panel 100, a plurality of gate lines GL and a plurality of data lines DL intersect with each other, and each of a plurality of pixels P is connected to a gate line GL and a data line DL. Specifically, one pixel P receives a gate signal from the gate driving part 300 through the gate line GL, receives a data voltage Vdata from the data driving part 400 through the data line DL, and receives a high-potential driving voltage ELVDD and a low-potential driving voltage ELVSS from the power supply unit 500.

The gate line GL supplies a scan signal SC and an emission control signal EM, and the data line DL supplies a data voltage Vdata. Additionally, according to various embodiments, the gate line GL can include a plurality of scan lines SCL supplying scan signals SC, and an emission control signal line EML supplying an emission control signal EM. Additionally, the plurality of pixels P can further include a power line VL to receive a reference voltage VREF and a reset voltage VAR.

Additionally, each pixel P includes a light-emitting element and a pixel circuit. The pixel circuit includes a plurality of switching elements, driving elements, and capacitors. Here, the switching element and the driving element can be configured with a thin film transistor. In the pixel circuit, the driving element controls the amount of current supplied to the light-emitting element according to a data voltage, thereby adjusting the amount of light emitted by the light-emitting element. Additionally, the plurality of switching elements operate the pixel circuit by receiving the scan signals SC supplied through the plurality of scan lines SCL and the emission control signal EM supplied through the emission control line EML.

The display panel 100 can be implemented as a non-transmissive display panel or a transmissive display panel. The transmissive display panel can be applied to a transparent display apparatus that displays an image on a screen allowing a real background object to be visible. The display panel 100 can be manufactured as a flexible display panel. The flexible display panel can be implemented as an OLED panel employing a plastic substrate.

On the display panel 100 a plurality of touch sensors can be disposed. Touch input can be sensed using separate touch sensors or through pixels P. The touch sensors can be disposed on the screen of the display panel as on-cell type or add on type, or be implemented as in-cell type touch sensors built in the display panel 100.

The controller 200 processes image data RGB input from a host system to be suitable to the size and resolution of the display panel 100, and supplies the resultant of the processing to the data driving part 400. The controller 200 generates a gate control signal GCS and a data control signal DCS by using synchronous signals input from the outside, such as a clock signal CLK, a data enable signal DE, a horizontal synchronous signal Hsync, and a vertical synchronous signal Vsync. By supplying the generated gate control signal GCS and data control signal DCS to the gate driving part 300 and data driving part 400, respectively, the controller 200 controls the gate driving part 300 and the data driving part 400.

The controller 200 can be configured to be combined with various processors, such as a microprocessor, a mobile processor, an application processor, or the like, depending on the device on which it is mounted.

The host system can be any one of a television (TV) system, a set-top box, a navigation system, a personal computer (PC), a home theater system, a mobile device, a wearable device, or a vehicle system.

The controller 200 generates signals so that the pixels P can be driven at various refresh rates. The refresh rate can be defined as the number of frames transmitted per second. For example, the controller 200 generates signals related to the driving so that the pixels P can be driven at a variable refresh rate when operating in a variable refresh rate (VRR) mode. For example, the controller 200 can simply change the speed of the clock signal, or generate a synchronization signal to allow a horizontal blank or a vertical blank to be formed.

The controller 200 generates a gate control signal GCS for controlling the operation timing of the gate driving part 300 and a data control signal DSC for controlling the operation timing of the data driving part 400 based on the timing signals Vsync, Hsync, and DE received from the host system. The controller 200 synchronizes the gate driving part 300 and the data driving part 400 by controlling the operation timing.

The gate driving part 300 supplies a scan signal SC to the gate line GL according to the gate control signal GCS supplied from the controller 200. The gate driving part 300 can be disposed on one or both sides of the display panel 100 in a GIP (Gate In Panel) manner.

In the organic light-emitting display apparatus, the gate driving part 300 supplies a scan signal SC and an emission control signal EM to the display panel 100. The scan signal SC can include a scan pulse that swings between the gate low voltage VGL and the gate high voltage VGH. The emission control signal EM includes an emission control signal pulse that swings between the gate low voltage VEL and the gate high voltage VEH. The scan pulse is synchronized with the data voltage Vdata to be used in selecting a line of pixels P to which data is to be written. The emission control signal pulse defines emission time of the pixels P.

The gate driving part 300 includes at least one light emission control signal driver 310 and at least one scan driving part 320. The emission control signal driver 310 outputs a emission control signal pulse in response to a start pulse and shift clock from the controller 200, and sequentially shifts the emission control signal pulse according to the shift clock. The scan driving part 320 outputs a scan pulse in response to the start pulse and shift clock from the controller 200, and shifts the scan pulse according to the shift clock timing.

The data driving part 400 converts image data RGB into data voltage Vdata according to a data control signal DCS supplied from the controller 200, and supplies the converted data voltage Vdata to the pixel P through the data line DL.

In FIG. 1, the data driving part 400 is illustrated as being disposed on one side of the display panel 100 in a single form, but the number and disposition positions of the data driving parts 400 are not limited thereto. The data driving part 400 can be configured with a plurality of integrated circuits (ICs), and be disposed on one side of the display panel 100 in multiple separate sections.

The power supply unit 500 uses a DC-DC converter to generate DC power required to drive the pixel array of the display panel 100, the gate driving part 300, and the data driving part 400. The DC-DC converter can include a charge pump, a regulator, a buck converter, a boost converter, or the like. The power supply unit 500 can receive a DC input voltage applied from the host system to generate DC voltage such as gate low voltages VGL and VEL, gate high voltages VGH and VEH, a high-potential driving voltage ELVDD, a low-potential driving voltage ELVSS, a reset voltage VAR, a reference voltage VREF, or the like. The gate low voltages VGL, VEL and the gate high voltages VGH, VEH are supplied to a level shifter and the gate driving part 300. The high-potential driving voltage ELVDD, the low-potential driving voltage ELVSS, the reset voltage VAR, and the reference voltage VREF are supplied to the pixels P.

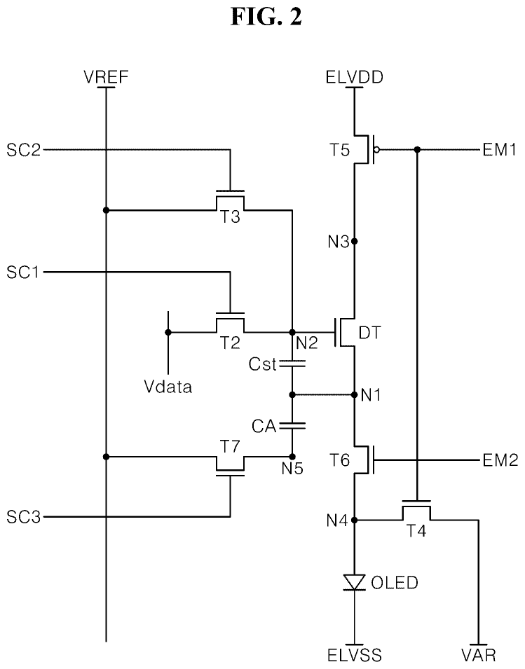

FIG. 2 is a circuit diagram of a pixel in an organic light-emitting display apparatus according to an embodiment of the present disclosure.

Referring to FIG. 2, each of the plurality of pixels P can include a pixel circuit having a driving transistor DT, and a light-emitting element OLED connected to the pixel circuit.

The pixel circuit can control a driving current flowing to the light-emitting element OLED to drive the light-emitting element OLED. The pixel circuit can include a driving transistor DT, second to seventh transistors T2 to T7, a storage capacitor Cst, and a compensation capacitor CA.

Each of the driving transistor DT and the second to seventh transistors T2 to T7 can include a first electrode, a second electrode, and a gate electrode. One of the first electrode and the second electrode can be a source electrode, and the other of the first electrode and the second electrode can be a drain electrode.

Each of the driving transistor DT and the second to seventh transistors T2 to T7 can be a P-type thin film transistor or an N-type thin film transistor. In an embodiment of FIG. 2, the driving transistor DT, the second, third, fourth, sixth, and seventh transistors T2, T3, T4, T6, and T7 can be N-type thin film transistors, and the fifth transistor T5 can be a P-type thin film transistor. Additionally, the N-type thin film transistor can be an oxide thin film transistor. The P-type thin film transistor can be a polycrystalline silicon thin film transistor.

As described above, each of the plurality of pixels includes the light-emitting element OLED, the driving transistor DT driving the light-emitting element OLED, the storage capacitor Cst with one electrode connected to the gate electrode of the driving transistor DT and the other electrode connected to the source electrode of the driving transistor DT, and the compensation capacitor CA with one electrode connected to the other electrode of the storage capacitor Cst and the source electrode of the driving transistor DT.

Additionally, each of the plurality of pixels includes a second transistor T2 with one electrode connected to the data voltage Vdata and the other electrode connected to the gate electrode of the driving transistor DT and the one electrode of the storage capacitor Cst, a third transistor T3 with one electrode connected to the reference voltage VREF and the other electrode connected to the gate electrode of the driving transistor DT and the one electrode of the storage capacitor Cst, and a fourth transistor T4 with one electrode connected to the anode electrode of the light-emitting element OLED and the other electrode connected to the reset voltage VAR.

Additionally, each of the plurality of pixels includes a fifth transistor T5 with one electrode connected to the high-potential driving voltage ELVDD and the other electrode connected to the drain electrode of a driving transistor DT, a sixth transistor T6 with one electrode connected to the source electrode of the driving transistor DT and the other electrode connected to the anode electrode of the light-emitting element OLED, and a seventh transistor T7 with one electrode connected to the reference voltage VREF and the other electrode connected to the other electrode of the compensation capacitor CA.

The driving transistor DT includes the source electrode connected to a first node N1, the gate electrode connected to a second node N2, and the drain electrode connected to a third node N3. The driving transistor DT provides a driving current to the light-emitting element OLED based on the data voltage Vdata applied to the gate electrode.

The light-emitting element OLED includes the anode electrode and the cathode electrode. The anode electrode of the light-emitting element OLED is connected to the fourth node N4, and the cathode electrode is connected to the low-potential driving voltage ELVSS.

The storage capacitor Cst can be connected or formed between the second node N2 and the first node N1. The storage capacitor Cst can store or maintain the data voltage Vdata. Additionally, the storage capacitor Cst can be used to sample the threshold voltage of the driving transistor DT.

The compensation capacitor CA can be connected or formed between the first node N1 and a fifth node N5. The compensation capacitor CA can be used to maintain the potential of the first node N1 corresponding to the source electrode of the driving transistor DT. Additionally, the compensation capacitor CA can be used to sample the threshold voltage of the driving transistor DT together with the storage capacitor Cst.

The second transistor T2 can include a first electrode connected to the data line DL (or receiving the data voltage Vdata), a second electrode connected to the second node N2, and a gate electrode receiving the first scan signal SC1. The second transistor T2 can be turned on in response to the first scan signal SC1, and can transmit the data voltage Vdata to the second node N2.

The third transistor T3 can include a first electrode receiving the reference voltage VREF, a second electrode connected to the second node N2, and a gate electrode receiving the second scan signal SC2. The third transistor T3 can be turned on in response to the second scan signal SC2, and can transmit the reference voltage VREF to the second node N2.

The fourth transistor T4 can include a first electrode receiving the reset voltage VAR, a second electrode connected to the fourth node N4, and a gate electrode receiving the first emission control signal EM1. The fourth transistor T4 can be turned on in response to the first emission control signal EM1, and can transmit the reset voltage VAR to the fourth node N4.

The fifth transistor T5 can include a first electrode receiving the high-potential driving voltage ELVDD, a second electrode connected to the third node N3, and a gate electrode receiving the first emission control signal EM1. The fifth transistor T5 can be turned on in response to the first emission control signal EM1, and can transmit the high-potential driving voltage ELVDD to the third node N3.

The sixth transistor T6 can include a first electrode connected to the first node N1, a second electrode connected to the fourth node N4, and a gate electrode receiving the second emission control signal EM2. The sixth transistor T6 can be turned on in response to the second emission control signal EM2, and can transmit a driving current controlled by the driving transistor DT to the light-emitting element OLED through the fourth node N4. Additionally, the sixth transistor T6 can be turned on in response to the second emission control signal EM2, and can transmit the reset voltage VAR transmitted by the fourth transistor T4 to the first node N1.

The seventh transistor T7 can include a first electrode receiving the reference voltage VREF, a second electrode connected to the fifth node N5, and a gate electrode receiving the third scan signal SC3. The seventh transistor T7 can be turned on in response to the third scan signal SC3, and can transmit the reference voltage VREF to the fifth node N5.

The display apparatus according to an embodiment of the present disclosure can operate as a variable refresh rate VRR mode display apparatus. The VRR mode can allow a pixel to operate at a constant frequency, operate at an increased refresh rate updating the data voltage Vdata when the pixel is required to be driven at a high speed, or operate at a decreased refresh rate when the power consumption is required to be reduced or the pixel is required to be driven at a low speed.

Each of the plurality of pixels P can perform only the refresh frame driving, or a combination of the refresh frame driving and the anode reset frame driving, according to the refresh rate. In the present disclosure, the refresh frame can be defined as a period during which the data voltage Vdata is updated, and the anode reset frame can be defined as a period during which the data voltage Vdata is maintained without being updated. In the present disclosure, one set period can be defined as a period during which a combination of a refresh frame and an anode reset frame is repeated.

For example, when the driving is performed at the refresh rate of 120 Hz, it can be performed only with the refresh frame 120 times within 1 second. One refresh frame period is 1/120=8.33 ms, and one set period is also 8.33 ms.

Additionally, when the driving is performed at the refresh rate of 60 Hz, it can be performed by alternating the refresh frame and the anode reset frame 60 times within 1 second. One refresh frame period and one anode reset frame period are each 0.5/60=8.33 ms, and one set period is 16.66 ms.

Additionally, when the driving is performed at the refresh rate of 1 Hz, it can be performed with one refresh frame and 119 anode reset frames within 1 second. One refresh frame period and one anode reset frame period are 1/120=8.33 ms, and one set period is 1 second.

The refresh frame charges the new data voltage Vdata to apply the new data voltage Vdata to the driving transistor DT, whereas the anode reset frame maintains and uses the data voltage Vdata of the previous frame. The anode reset frame can also be referred to as a hold frame in the sense that the data voltage Vdata of the previous frame is maintained and used as it was.

First, the driving of the light-emitting element and the pixel circuit of the refresh frame will be described.

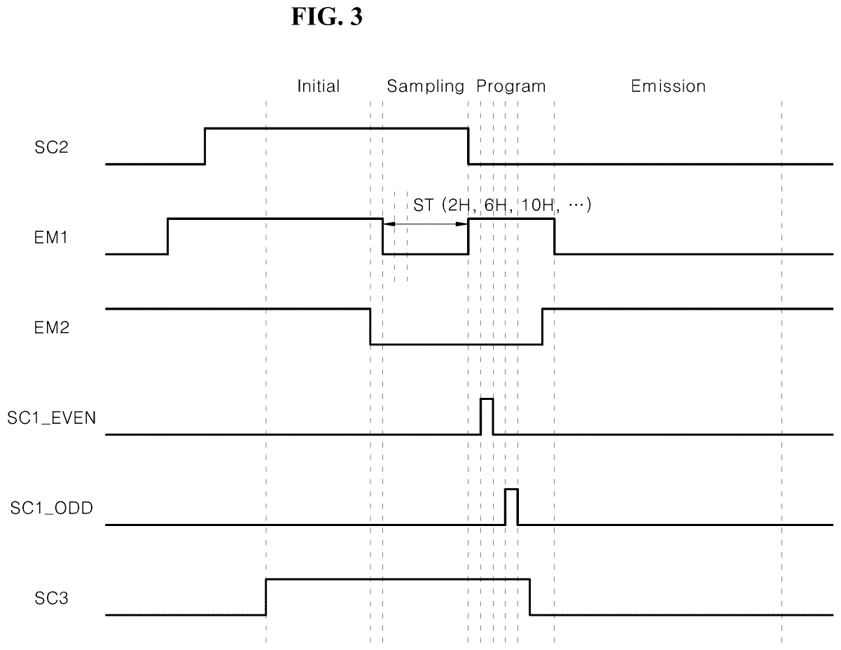

FIG. 3 is a timing diagram illustrating an operation of a pixel in an organic light-emitting display apparatus according to an embodiment of the present disclosure.

Referring to FIG. 3, the operation of the refresh frame can include an initialization period, a sampling period, a program period, and an emission period.

Referring to FIGS. 2 and 3, the operation of the pixel circuit can include an initialization period during the refresh frame. The initialization period is a period for initializing the first node N1, second node N2, fourth node N4, and fifth node N5 of the pixel circuit. During this initialization period, the storage capacitor Cst and the gate electrode of the driving transistor DT, which are connected to the second node N2, can be initialized; the source electrode of the driving transistor DT connected to the first node N1 can be initialized; the anode electrode of the light-emitting element OLED connected to the fourth node N4 can be initialized; and the compensation capacitor CA connected to the fifth node N5 can be initialized.

In the initialization period, the second scan signal SC2, the third scan signal SC3, the first emission control signal EM1, and the second emission control signal EM2 are applied with a high voltage, and the third transistor T3, the fourth transistor T4, the sixth transistor T6, and the seventh transistor T7 are turned on. As the third transistor T3, the fourth transistor T4, the sixth transistor T6, and the seventh transistor T7 are turned on, the second node N2 and the fifth node N5 can be initialized to the reference voltage VREF, and the fourth node N4 and the first node N1 can be initialized to the reset voltage VAR.

The operation of the pixel circuit can include a sampling period during the refresh frame. The sampling period is a period for sampling the threshold voltage Vth of the driving transistor DT. During this sampling period, the threshold voltage Vth of the driving transistor DT can be sampled through the storage capacitor Cst and the compensation capacitor CA.

In the sampling period, the second scan signal SC2 and the third scan signal SC3 are high voltages; the first emission control signal EM1 is applied with a low voltage; and the third transistor T3, the fifth transistor T5, the seventh transistor T7, and the driving transistor DT are turned on. As the third transistor T3, the fifth transistor T5, the seventh transistor T7, and the driving transistor DT are turned on, the high-potential driving voltage ELVDD is transmitted to the third node N3 and the second node N2 and the fifth node N5 are maintained at the reference voltage VREF, so that the threshold voltage of the driving transistor DT can be transmitted to the first node N1 and sampled.

The operation of the pixel circuit can include a program period during the refresh frame. The program period is a period in which the data voltage Vdata is stored in the storage capacitor Cst.

During the program period, the first scan signal SC1, the third scan signal SC3, and the first emission control signal EM1 are applied with a high voltage, and the second transistor T2, the fourth transistor T4, and the seventh transistor T7 are turned on. The first scan signal SC1 can include the odd-numbered first scan signal SC1_ODD provided to the odd-numbered gate line and the even-numbered first scan signal SC1_EVEN provided to the even-numbered gate line.

In the program period, as the second transistor T2, the fourth transistor T4, and the seventh transistor T7 are turned on, the data voltage Vdata is transmitted to the second node N2, the reset voltage VAR is transmitted to the fourth node N4, and the fifth node N5 is maintained at the reference voltage VREF, so that the data voltage Vdata is stored in the storage capacitor Cst.

The operation of the pixel circuit can include an emission period during the refresh frame. The emission period is a period in which the light-emitting element OLED emits light with a driving current corresponding to the data voltage Vdata stored in the storage capacitor Cst while offsetting the sampled threshold voltage Vth of the driving transistor DT.

During the emission period, the first emission control signal EM1 is applied with a low voltage, the second emission control signal EM2 is applied with a high voltage, and the fifth transistor T5, the sixth transistor T6, and the driving transistor DT are turned on. As the fifth transistor T5, the sixth transistor T6, and the driving transistor DT are turned on, the high-potential driving voltage ELVDD is transmitted to the third node N3, and a driving current corresponding to the data voltage Vdata is provided to the light-emitting element OLED.

Next, the driving of the light-emitting element and the pixel circuit of the anode reset frame will be described.

The operation of the pixel circuit can include an anode reset period during the anode reset frame. The anode reset frame is a period in which the data voltage Vdata of the refresh frame is maintained and used as it was. Therefore, as for the anode reset frame, unlike the case of the refresh frame, an initialization period, a sampling period, and a program period are unnecessary.

During the anode reset period, the first emission control signal EM1 and the second emission control signal EM2 are applied with a high voltage, and the fourth transistor T4 and the sixth transistor T6 are turned on. As the fourth transistor T4 and the sixth transistor T6 are turned on, the first node N1 and the fourth node N4 can be reset to the reset voltage VAR, and the second node N2 can be maintained at the data voltage Vdata.

Additionally, the operation of the pixel circuit can include an emission period during the anode reset frame. The operation of the emission period of the anode reset frame is the same as the operation of the emission period of the refresh frame.

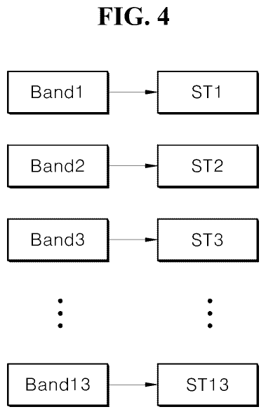

FIG. 4 is a diagram illustrating that the sampling time of FIG. 3 is individually set according to the luminance band according to an example of the present disclosure.

In a pixel structure to which an oxide TFT is applied as shown in FIG. 2, the optimal conditions of the sampling time ST satisfying the excellent TLS characteristics of the high-luminance band and the low-luminance band are different. As shown in FIG. 4, by applying an optimal sampling time for each luminance band, the present disclosure is intended to improve TLS characteristics in all luminance bands.

The luminance band can be divided into a plurality of bands Band1, Band2, Band3, . . . , and Band13 representing a luminance range from a low luminance to a high luminance, and a sampling time can be individually set for each of the plurality of bands. For example, a first sampling time ST1 can be set to the first band Band1; a second sampling time ST2 can be set to the second band Band2; a third sampling time ST3 can be set to the third band Band3; and a thirteenth sampling time ST13 can be set to the thirteenth band Band13. Here, when the first band Band1 is a low-luminance band and the thirteenth band Band13 is a high-luminance band, the sampling time can be set so that the sampling time becomes longer as it goes from the low-luminance band to the high-luminance band. For example, in the low-luminance band, the sampling time can be varied to be short, and in the high-luminance band, the sampling time can be varied to be long.

In the turn-on state of the third transistor T3, the turn-on period of the fifth transistor T5 can be defined as the sampling period, and the sampling period can be varied by controlling the turn-on time point of the fifth transistor T5 according to the luminance band. For example, the sampling time for sensing the threshold voltage of the driving transistor DT represents a period during which both the second scan signal SC2 and the first emission control signal EM1 are on. Since the third transistor T3 is an NMOS TFT, it is turned on when the second scan signal SC2 is at the high logic level, and since the fifth transistor T5 is a PMOS TFT, it is turned on when the first emission control signal EM1 is at the low logic level.

In a display panel having a pixel to which an oxide TFT is applied, the shorter the sampling time, the better the TLS in the low-luminance band, and the longer the sampling time, the better the TLS in the high-luminance band. The equation below represents the TLS calculation equation.

$$TLS [ \% / ° C . ] = \frac{( luminance @ {T}_{1} - luminance @ {T}_{2} )}{( luminance @ {T}_{1} ) \times ( {T}_{1} - {T}_{2} )} \times 100$$

where, T1 and T2 denote evaluation temperature conditions, luminance@T1 indicates the luminance at the temperature of T1, and luminance@T2 indicates the luminance at the temperature of T2.

As described above, the display apparatus of the present disclosure can apply an optimal sampling time for each luminance band so that TLS characteristics can be improved in all luminance bands. The sampling time can be varied to be short in a low-luminance band, and to be long in a high-luminance band.

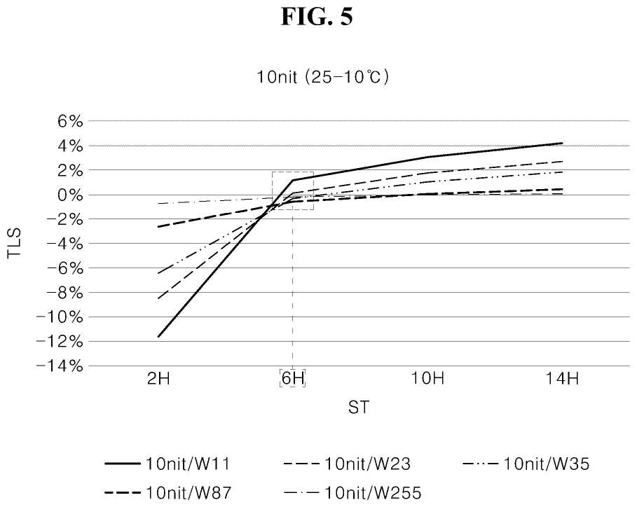

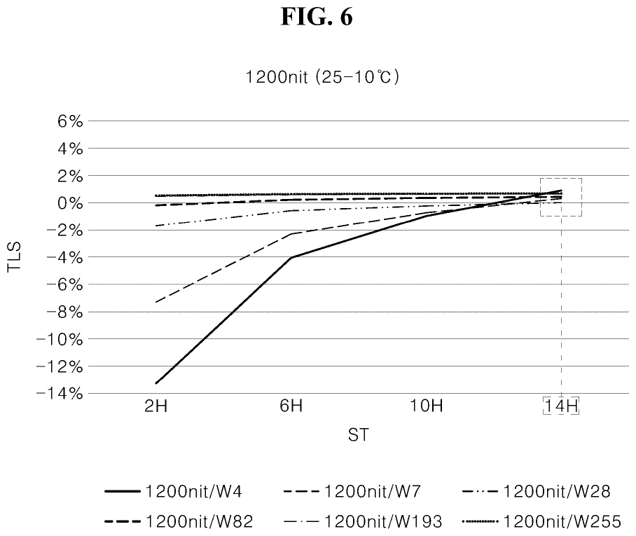

FIG. 5 is a diagram showing an optimal sampling time in a low-luminance band. FIG. 6 is a diagram illustrating an optimal sampling time in a high-luminance band.

Referring to FIG. 5, in the case where data voltages corresponding to image data W11, W23, W35, W87, and W255 are applied respectively, under a condition of a low-luminance band, for example, 10 nit (25-10° C.), the TLS characteristics of the low-luminance band can be improved when the sampling time of 6H is applied. Here, image data W11, W23, W35, W87, and W255 represent the grayscale values of 11, 23, 35, and 255 for the white color. And 6H represents six times one horizontal period.

Additionally, referring to FIG. 6, in the case where data voltages corresponding to image data W4, W7, W28, W82, W193, and W255 are applied respectively, under a condition of a high-luminance band, for example, 1200 nit (25-10° C.), the TLS characteristics of the high-luminance band can be improved when the sampling time of 14H is applied. Here, image data W4, W7, W28, W82, W193, and W255 represent the grayscale values of 4, 7, 28, 82, 193, and 255 for the white color. And 14H represents 14 times one horizontal period.

As described above, the display apparatus can vary the sampling time to be short in a low-luminance band, and can vary the sampling time to be long in a high-luminance band so that the TLS characteristics for every band can be improved.

The various features of the present disclosure can be briefly summarized as follows.

A display apparatus according to an embodiment of the present disclosure includes a light-emitting element; a driving transistor driving the light-emitting element; a storage capacitor sampling a threshold voltage of the driving transistor during a sampling period, and programming a data voltage during a program period; and at least one thin film transistor transmitting at least one of the data voltage, a reference voltage, and a reset voltage, and varies the sampling period according to a luminance band.

According to an embodiment of the present disclosure, the luminance band can be divided into a plurality of bands representing a luminance range from a low luminance to a high luminance, and the sampling period can be individually set for each of the plurality of bands.

According to an embodiment of the present disclosure, the sampling period can be varied to have a longer time in a step-by-step manner as it goes from a low-luminance band to a high-luminance band.

According to an embodiment of the present disclosure, the driving transistor and the at least one thin film transistor can be N-type thin film transistors.

According to an embodiment of the present disclosure, the display apparatus can further include a compensation capacitor with one electrode connected to one electrode of the storage capacitor and a source electrode of the driving transistor, and another electrode connected to the reference voltage.

According to an embodiment of the present disclosure, the at least one thin film transistor can include a first transistor with one electrode connected to the data voltage and another electrode connected to a gate electrode of the driving transistor and another electrode of the storage capacitor; a second transistor with one electrode connected to the reference voltage and another electrode connected to the gate electrode of the driving transistor and the other electrode of the storage capacitor; a third transistor with one electrode connected to an anode electrode of the light-emitting element and another electrode connected to the reset voltage; a fourth transistor with one electrode connected to a high-potential driving voltage and another electrode connected to a drain electrode of the driving transistor; a fifth transistor with one electrode connected to the source electrode of the driving transistor and another electrode connected to the anode electrode of the light-emitting element; and a sixth transistor with one electrode connected to the reference voltage and another electrode connected to the other electrode of the compensation capacitor.

According to an embodiment of the present disclosure, the driving transistor, the first, second, third, fifth, and sixth transistors can be N-type thin film transistors, and the fourth transistor can be a P-type thin film transistor.

According to an embodiment of the present disclosure, in a turn-on state of the second transistor, a turn-on period of the fourth transistor can be defined as the sampling period, and the sampling period can be varied by controlling a turn-on time point of the fourth transistor according to the luminance band.

According to an embodiment of the present disclosure, in a turn-on state of the second transistor, the third transistor, and the fifth transistor, an initialization period can be defined as from a turn-on time point of the sixth transistor to a turn-off time point of the fifth transistor.

According to an embodiment of the present disclosure, during the initialization period, the gate electrode of the driving transistor and the other electrode of the compensation capacitor can be initialized to the reference voltage, and the anode electrode of the light-emitting element and the source electrode of the driving transistor can be initialized to the reset voltage.

A display apparatus according to an embodiment of the present disclosure includes a display panel in which a plurality of pixels are disposed, wherein each of the plurality of pixels include a light-emitting element; a driving transistor driving the light-emitting element; a storage capacitor with one electrode connected to a gate electrode of the driving transistor and another electrode connected to a source electrode of the driving transistor; a compensation capacitor with one electrode connected to the other electrode of the storage capacitor and the source electrode of the driving transistor; a first transistor with one electrode connected to a data voltage and another electrode connected to the gate electrode of the driving transistor and the one electrode of the storage capacitor; a second transistor with one electrode connected to a reference voltage and another electrode connected to the gate electrode of the driving transistor and the one electrode of the storage capacitor; a third transistor with one electrode connected to an anode electrode of the light-emitting element and another electrode connected to a reset voltage; a fourth transistor with one electrode connected to a high-potential driving voltage and another electrode connected to a drain electrode of the driving transistor; a fifth transistor with one electrode connected to the source electrode of the driving transistor and another electrode connected to the anode electrode of the light-emitting element; and a sixth transistor with one electrode connected to the reference voltage and another electrode connected to another electrode of the compensation capacitor. According to the display apparatus, in a turn-on state of the second transistor, a turn-on period of the fourth transistor is defined as a sampling period, and the sampling period is varied by controlling a turn-on time point of the fourth transistor according to a luminance band.

According to an embodiment of the present disclosure, the luminance band can be divided into a plurality of bands representing a luminance range from a low luminance to a high luminance, and the sampling period can be individually set for each of the plurality of bands.

According to an embodiment of the present disclosure, the sampling period can be varied to have a longer time in a step-by-step manner as it goes from a low-luminance band to a high-luminance band.

According to an embodiment of the present disclosure, the driving transistor, the first, second, third, fifth, and sixth transistors can be N-type thin film transistors, and the fourth transistor can be a P-type thin film transistor.

According to an embodiment of the present disclosure, in a turn-on state of the second transistor, the third transistor, and the fifth transistor, an initialization period can be defined as from a turn-on time point of the sixth transistor to a turn-off time point of the fifth transistor.

According to an embodiment of the present disclosure, during the initialization period, the gate electrode of the driving transistor and the other electrode of the compensation capacitor can be initialized to the reference voltage, and the anode electrode of the light-emitting element and the source electrode of the driving transistor can be initialized to the reset voltage.

While the embodiments of the present disclosure have been described in detail with reference to the accompanying drawings, it should be understood by a person skilled in the art that the present disclosure is not necessarily limited to the above embodiments, and the above embodiments can be practiced in various modified forms without departing from the technical idea of the present disclosure. Accordingly, the embodiments disclosed in the present disclosure are not intended to limit the technical idea of the present disclosure but to explain the technical idea of the present disclosure, and the scope of the technical idea of the present disclosure is not limited by these embodiments. Therefore, it should be understood that the embodiments described above are given only as an example in all respects but not for the purpose of limiting the disclosure. The scope of protection of the present disclosure should be interpreted by the claims, and all technical ideas within the equivalent scope should be interpreted as being included in the scope of the rights of the present disclosure.

What is claimed is:

1. A display apparatus comprising:
a light-emitting element;
a driving transistor configured to drive the light-emitting element;
a storage capacitor configured to sample a threshold voltage of the driving transistor during a sampling period, and program a data voltage during a program period; and
at least one thin film transistor configured to transmit at least one of the data voltage, a reference voltage, and a reset voltage,
wherein the display apparatus varies the sampling period according to a luminance band.

2. The display apparatus of claim 1, wherein the luminance band is divided into a plurality of bands representing a luminance range from a low luminance to a high luminance, and the sampling period is individually set for each of the plurality of bands.

3. The display apparatus of claim 2, wherein the sampling period is varied to have a longer time in a step-by-step manner from a low-luminance band to a high-luminance band.

4. The display apparatus of claim 1, wherein the driving transistor and the at least one thin film transistor are N-type thin film transistors.

5. The display apparatus of claim 1, further comprising:
a compensation capacitor having one electrode connected to one electrode of the storage capacitor and a source electrode of the driving transistor, and another electrode connected to the reference voltage.

6. The display apparatus of claim 5, wherein the at least one thin film transistor includes:
a first transistor having one electrode connected to the data voltage and another electrode connected to a gate electrode of the driving transistor and another electrode of the storage capacitor;
a second transistor having one electrode connected to the reference voltage and another electrode connected to the gate electrode of the driving transistor and the another electrode of the storage capacitor; and
a third transistor having one electrode connected to an anode electrode of the light-emitting element and another electrode connected to the reset voltage.

7. The display apparatus of claim 6, wherein the at least one thin film transistor further includes:
a fourth transistor having one electrode connected to a high-potential driving voltage and another electrode connected to a drain electrode of the driving transistor;
a fifth transistor having one electrode connected to the source electrode of the driving transistor and another electrode connected to the anode electrode of the light-emitting element; and
a sixth transistor having one electrode connected to the reference voltage and another electrode connected to the another electrode of the compensation capacitor.

8. The display apparatus of claim 7, wherein the driving transistor, the first, second, third, fifth, and sixth transistors are N-type thin film transistors, and the fourth transistor is a P-type thin film transistor.

9. The display apparatus of claim 7, wherein, in a turn-on state of the second transistor, a turn-on period of the fourth transistor is defined as the sampling period, and the sampling period is varied by controlling a turn-on time point of the fourth transistor according to the luminance band.

10. The display apparatus of claim 7, wherein, in a turn-on state of the second transistor, the third transistor, and the fifth transistor, an initialization period is defined as from a turn-on time point of the sixth transistor to a turn-off time point of the fifth transistor.

11. The display apparatus of claim 10, wherein during the initialization period, the gate electrode of the driving transistor and the another electrode of the compensation capacitor are initialized to the reference voltage, and the anode electrode of the light-emitting element and the source electrode of the driving transistor are initialized to the reset voltage.

12. A display apparatus comprising:
a display panel including a plurality of pixels,
wherein each of at least one of the plurality of pixels includes:
a light-emitting element;
a driving transistor configured to drive the light-emitting element;
a storage capacitor having one electrode connected to a gate electrode of the driving transistor and another electrode connected to a source electrode of the driving transistor;
a compensation capacitor having one electrode connected to the another electrode of the storage capacitor and the source electrode of the driving transistor;
a first transistor having one electrode connected to a data voltage and another electrode connected to the gate electrode of the driving transistor and the one electrode of the storage capacitor;
a second transistor having one electrode connected to a reference voltage and another electrode connected to the gate electrode of the driving transistor and the one electrode of the storage capacitor;
a third transistor having one electrode connected to an anode electrode of the light-emitting element and another electrode connected to a reset voltage; and
a fourth transistor having one electrode connected to a high-potential driving voltage and another electrode connected to a drain electrode of the driving transistor,
wherein, in a turn-on state of the second transistor, a turn-on period of the fourth transistor is defined as a sampling period, and the sampling period is varied by controlling a turn-on time point of the fourth transistor according to a luminance band.

13. The display apparatus of claim 12, wherein each of at least one of the plurality of pixels further includes:
a fifth transistor having one electrode connected to the source electrode of the driving transistor and another electrode connected to the anode electrode of the light-emitting element; and
a sixth transistor having one electrode connected to the reference voltage and another electrode connected to another electrode of the compensation capacitor.

14. The display apparatus of claim 12, wherein the luminance band is divided into a plurality of bands representing a luminance range from a low luminance to a high luminance, and the sampling period is individually set for each of the plurality of bands.

15. The display apparatus of claim 14, wherein the sampling period is varied to have a longer time in a step-by-step manner as it goes from a low-luminance band to a high-luminance band.

16. The display apparatus of claim 15, wherein for a low luminance band of 10 nit, the sampling period is set to 6H, and for a high luminance band of 1200 nit, the sampling period is set to 14H.

17. The display apparatus of claim 13, wherein the driving transistor, the first, second, third, fifth, and sixth transistors are N-type thin film transistors, and the fourth transistor is a P-type thin film transistor.

18. The display apparatus of claim 13, wherein, in a turn-on state of the second transistor, the third transistor, and the fifth transistor, an initialization period is defined as from a turn-on time point of the sixth transistor to a turn-off time point of the fifth transistor.

19. The display apparatus of claim 18, wherein during the initialization period, the gate electrode of the driving transistor and the another electrode of the compensation capacitor are initialized to the reference voltage, and the anode electrode of the light-emitting element and the source electrode of the driving transistor are initialized to the reset voltage.
